(19) United States
(12) Patent Application Publication
(10) Pub. No.: US 2023/0365024 A1
(43) Pub. Date: Nov. 16, 2023

(54) SYSTEM AND METHOD FOR CHARGING AN AUXILIARY BATTERY OF A VEHICLE

(71) Applicant: R.A. Phillips Industries, Inc., Santa Fe Springs, CA (US)

(72) Inventors: Alexander Reid, Huntsville, AL (US); Daniel William Forthoffer, Birmingham, MI (US)

(21) Appl. No.: 18/316,658

(22) Filed: May 12, 2023

Related U.S. Application Data
(60) Provisional application No. 63/341,321, filed on May 12, 2022.

(51) Int. Cl. B60L 58/12; B60L 53/51; B60L 1/14; B60L 58/16

(52) U.S. Cl. CPC B60L 58/12; B60L 1/14; B60L 53/51; B60L 58/16; B60L 2240/545; B60L 2240/547

(57) ABSTRACT

A method of determining a power draw limit of a battery charger of a vehicle includes performing a power reversal to supply electrical power from an auxiliary battery of the vehicle to one or more vehicle components, measuring electrical power supplied to the one or more vehicle components by the auxiliary battery, determining validity of the measurement, and in response to the determining the validity of the measurement, determining the power draw limit based on the measured electrical power and a power limit of a vehicle circuit coupled to the battery charger.

### CROSS-REFERENCE TO RELATED APPLICATION(S)

This application claims priority to, and the benefit of, U.S. Provisional Application No. 63/341,321 (“LIFTGATE CHARGER”), filed on May 12, 2022, the entire content of which is incorporated herein by reference.

### FIELD

The invention relates to the field of vehicle power systems.

### BACKGROUND

Most goods within a country or state are transported by semi-trailers. Trailers may make tens of stops on a daily basis to load and unload cargo. In order to reduce the risk of injury to drivers and damage to the goods being delivered, many daily delivery trailers utilize liftgates that can lower/raise freight to/from the ground. Generally, liftgates are powered by 12 volt batteries and use a large amount of power, which necessitates charging in-between stops. To maximize battery charging between stops, chargers need to draw as much current as possible.

The liftgate battery charger is often connected to the auxiliary (AUX) power line on the SAE (society of automobile engineers) J560 connector. It shares this circuit with the anti-lock braking system (ABS) or the electronic braking system (EBS), and any other accessories on the trailer that draw power. This circuit is generally in line with a 30 Amp fuse in the tractor. In the related art, liftgate battery chargers generally do not have a current control mechanism, which leads to blown truck fuses and failed ABS system tests. When the 30 amp fuse is blown, the fuse must be replaced before the liftgate battery can continue charging.

The above information disclosed in this Background section is only for enhancement of understanding of the background of the invention and therefore it may contain information that does not form the prior art that is already known to a person of ordinary skill in the art.

### SUMMARY

Aspects of embodiments of the invention are directed toward a battery charger (e.g., a liftgate battery charger) that is capable of controlling the charge power made available to an auxiliary battery that drives a liftgate based on availability of different current inputs and a number of conditions. According to some embodiments, the battery charger can perform a power limit test to determine the current being used by all other devices on its input circuit to determine the current that the charger can safely use to charge the auxiliary battery. In some embodiments, the charger is capable of communicating diagnostic health and status information via one or more of a wired (e.g., through CAN bus) connection and a wireless (e.g., Bluetooth) connection. This enables technicians and drivers in the field to determine the health of the battery charging system. It also informs the user when the current limiting method is working properly. The battery charger improves the technician’s ability to test and diagnose trailer systems, as well as reduce downtime due to blown truck fuses and failed diagnostic tests, thus reducing the maintenance hours required to maintain the system.

According to some embodiments of the invention, there is provided a method of determining a power draw limit of a battery charger of a vehicle, the method including:

performing a power reversal to supply electrical power from an auxiliary battery of the vehicle to one or more vehicle components; measuring electrical power supplied to the one or more vehicle components by the auxiliary battery; determining validity of the measurement; and in response to determining the validity of the measurement, determining the power draw limit based on the measured electrical power and a power limit of a vehicle circuit coupled to the battery charger.

In some embodiments, the performing the power reversal includes: coupling the auxiliary battery to an auxiliary power line of the vehicle that is coupled to the one or more vehicle components; and decoupling an input of the battery charger from the auxiliary power line.

In some embodiments, the method further includes: determining that conditions for performing the power reversal are met, wherein performing the power reversal is in response to the determining that the conditions for performing the power reversal are met.

In some embodiments, the determining that conditions for performing the power reversal are met includes: detecting an input power cycle; and determining that at least one of a first condition, a second condition, and a third condition are met, the first condition being a second period of time having passed since the input power cycle, the second condition being the battery charger not being in a safe mode, and the third condition being a number of input power cycles since a previous power reversal is greater than or equal to a threshold.

In some embodiments, the battery charger is configured to enter the safe mode in response to determining one or more of: detecting a brake signal at a brake light input of the vehicle, and detecting a drop in an input voltage of the battery charger during a current ramp up.

In some embodiments, the detecting the input power cycle includes: detecting a voltage collapse at an input of the battery charger; and determining that the voltage collapse has lasted for a first period of time.

In some embodiments, the determining the validity of the measurement includes: stopping flow of current from the auxiliary battery to the one or more vehicle components; measuring a line voltage of an auxiliary power line of the vehicle that is coupled to the one or more vehicle components; determining that electrical power has not been restored at the auxiliary power line based on the line voltage; and identifying the measurement as valid.

In some embodiments, that the electrical power has not been restored at the auxiliary power line by measuring the line voltage as zero volts.

In some embodiments, the determining the power draw limit includes: calculating the power draw limit as a difference between the power limit of the vehicle circuit and the measured electrical power.

In some embodiments, the vehicle is a tractor-trailer, and the one or more vehicle components include at least one of a solar charger, and a telematics device.

According to some embodiments of the invention, there is provided a method of charging an auxiliary battery of a vehicle by a charging system, the method including: receiving, by a battery charger of the charging system, solar charging data from a solar charger of the charging system; identifying, by the battery charger, power output of the solar charger to the auxiliary battery based on the solar charging data; determining, by the battery charger, a state of charge (SOC) of the auxiliary battery based on the solar charging data and internal charging data of the battery charger; and in response to determining that the state of charge of the auxiliary battery is greater than or equal to an SOC threshold and the power output of the solar charger is less than a power threshold, supplying, by the battery charger, electrical power to the auxiliary battery to supplement charging by the solar charger.

In some embodiments, the method further includes: in response to determining that the state of charge of the auxiliary battery is less than the SOC threshold, supplying, by the battery charger, electrical power to the auxiliary battery to supplement charging by the solar charger.

In some embodiments, the method further includes: in response to determining that the state of charge of the auxiliary battery is less than the SOC threshold or that the power output of the solar charger is greater than or equal to the power threshold, not supplying, by the battery charger, electrical power to the auxiliary battery.

In some embodiments, the solar charger is configured to receive electrical power from one or more solar panels and to supply regulated power to the auxiliary battery.

In some embodiments, the battery charger is configured to receive electrical power from an auxiliary power line of the vehicle and to supply regulated power to the auxiliary battery.

In some embodiments, the SOC threshold is 90%, and the power threshold is 12 W.

In some embodiments, the solar charge data includes data indicating status of the solar charger as charging or non-charging, an output power level of the solar charger, and historical data indicating amount of energy delivered to the auxiliary battery since last communication with the battery charger, and the internal charging data includes output power level of the battery charger and cumulative amount of energy provided to the auxiliary battery over time by the battery charger.

According to some embodiments of the invention, there is provided a charger system including: a battery charger configured to receive electrical power from an auxiliary power line of a vehicle and to charge an auxiliary battery of the vehicle; a solar charger configured to receive electrical power from one or more solar panels of the vehicle and to supply electrical power to the auxiliary battery independent from the battery charger, the solar charger being further configured to provide solar charging data to the battery charger, wherein the battery charger is configured to determine at least one of a state of charge (SOC) and a state of health (SOH) of the auxiliary battery based on the solar charging data and internal charging data of the battery charger, and to transmit prognostic data corresponding to the auxiliary battery to an external user device, the prognostic data including the at least one of the SOC and SOH of the auxiliary battery.

In some embodiments, the solar charge data includes data indicating status of the solar charger as charging or non-charging, an output power level of the solar charger, and historical data indicating amount of energy delivered to the auxiliary battery since last communication with the battery charger, and the internal charging data includes output power level of the battery charger and cumulative amount of energy provided to the auxiliary battery over time by the battery charger.

In some embodiments, the battery charger is configured to monitor and transmit to the external user device at least one of: faulty status of the auxiliary battery indicating inability to charge, fault reports received from the solar charger, a voltage of the auxiliary power line, ambient temperature of the battery charger, internal temperature of the battery charger, temperature of the auxiliary battery, output power of the battery charger, cumulative amount of energy provided to the auxiliary battery over time by each of the liftgate and solar chargers, a lifetime liftgate cycle counter, and a trip liftgate cycle counter.

Other aspects, features, and characteristics that are not described above will be more clearly understood from the accompanying drawings, claims, and detailed description.

### BRIEF DESCRIPTION OF THE DRAWINGS

The accompanying drawings, together with the specification, illustrate exemplary embodiments of the invention, and, together with the description, serve to explain aspects of embodiments of the invention. In the drawings, like reference numerals are used throughout the figures to reference like features and components. The figures are not necessarily drawn to scale. The above and other features and aspects of the invention will become more apparent by the following detailed description of illustrative embodiments thereof with reference to the attached drawing, in which:

FIG. 1 is a block diagram of a vehicle having a tractor and a trailer and employing a charging system for charging an auxiliary battery of the vehicle, according to some embodiments of the present disclosure.

FIG. 2 is a block diagram illustrating a first configuration of the charging system, according to some embodiments of the present disclosure.

FIG. 3 is a flow diagram illustrating a process of prioritizing solar charging by a battery charger of the charging system, according to some embodiments of the present disclosure.

FIG. 4 is a block diagram illustrating a second configuration of the charging system, according to some embodiments of the present disclosure.

FIG. 5 illustrates a schematic diagram of the battery charger according to some embodiments of the present disclosure.

FIG. 6 is a flow diagram illustrating a process of determining a power draw limit of the battery charger according to some embodiments of the present disclosure.

FIG. 7 is a flow diagram illustrating a process of determining whether the conditions for performing the power reversal are met, according to some embodiments of the present disclosure.

FIG. 8 is a flow diagram illustrating a process of determining whether the measurement performed in the power limit test is valid, according to some embodiments of the present disclosure.

### DETAILED DESCRIPTION

The detailed description set forth below is intended as a description of example embodiments of the invention, and is not intended to represent the only forms in which the invention may be constructed or utilized. The description sets forth the features of the invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

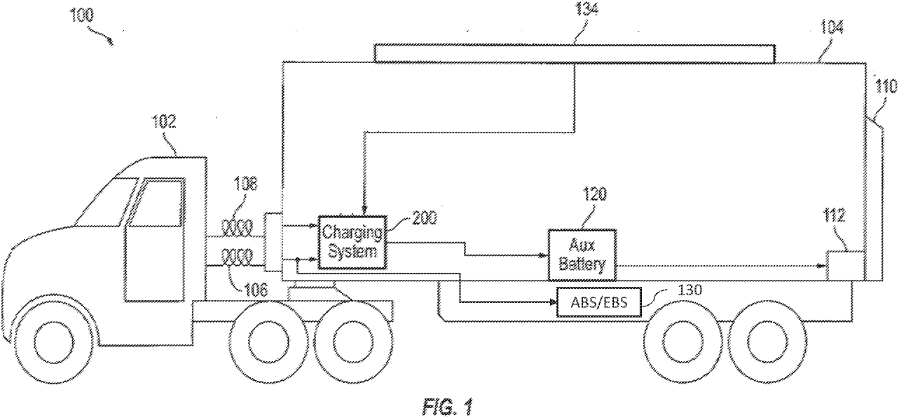

FIG. 1 is a block diagram of a vehicle 100 having a tractor 102 and a trailer 104 and employing a charging system 200 for charging an auxiliary battery (e.g., a liftgate battery) 120 (that is powering a liftgate 110) of the vehicle 100, according to some embodiments of the present disclosure. The auxiliary battery 120 may include one or more lead acid batteries, valve-regulated lead acid batteries, absorbent glass mat (AGM) batteries, and/or the like.

In some embodiments, the electrical system of the tractor 102 of the vehicle 100 supplies electrical power to the electrical system of the trailer 104 via trailer connectors including a first connector (e.g., a SAE J560 connector) 106 and a second connector (e.g., a single/multi-pole stinger cord) 108.

The first connector 106, which generally provides power to the anti-lock braking system (ABS) or the electronic braking system (EBS) 130 of the trailer 104, is coupled to the tractor at a SAE J560 connection (which may at the back of the tractor 102), and may supply a current of up to about 30 A to the electrical system of the trailer 104 (e.g., via an auxiliary wire (or blue wire) of the J560 connection). The first connector 106 is indirectly coupled to the tractor battery 152, that is, the first connector 106 is electrically routed to the tractor battery 152 through an auxiliary circuit 150, which may include, for example, a dashboard of a tractor 102 and its constituents components such as, an internal electronic control module (ECU) system, and other components such as fuses, and relays, and/or the like. As such, the indirect connection between the tractor battery and the first connector 106 is also switchable, and may only be established when, for example, the ignition of the tractor 102 is ON and the tractor engine is ON, and/or when another switch (e.g., a bypass switch) is ON to enable power to be supplied to the second connector without having the keys in the tractor 102.

The second connector 108, which may be a secondary source of power to the electrical system of the trailer 104, is directly coupled to the battery or alternator of the tractor 102 through, for example, a single/dual pole socket at the tractor 102 (e.g., at the junction box of the tractor 102). As a result, the direct connection between the tractor battery or alternator and the first connector 106 is a physical connection that is non-switchable, that is, the electrical connection is present and active irrespective of the tractor ignition being ON or OFF. In some examples, the direct connection may include a fuse, a circuit breaker, and/or one or more mechanical terminals/ports with negligible electrical impedance.

According to some embodiments, the trailer 104 includes a liftgate 110 driven by a trailer motor (or liftgate motor) 112, an auxiliary battery 120 for powering the trailer motor 112, and a charging system 200 for charging the auxiliary battery 120 and maintaining the voltage at the auxiliary battery 120 within an operable range (e.g., about 13 VDC to about 14.4 VDC). In some embodiments of the invention, the charging system 200 may draw electrical power from the first and second connectors 106 and 108. The trailer 104 may further be equipped with auxiliary power sources, such as solar panels 134, which, according to some embodiments, act as independent sources of electrical power for charging the auxiliary battery 120 by the charging system 200.

In some embodiments, the charging system 200 utilizes auxiliary sources of power to supplement the electrical power drawn from the tractor 102 through the first and second connectors 106 and 108 as, in some examples, power drawn from the tractor 102 may not be sufficient for charging the auxiliary battery 120. For example, while the first connector 106 may be able to provide ample current (e.g., about 30 A), power transmission through the first connector 106 may be available only when the keys of the vehicle 100 are in the ignition, which may make the vehicle susceptible to theft when idle and lead to inadvertent draw of other auxiliary loads, such as the tractor’s ECU, air conditioning unit, heating unit, microwave, and/or the like. By utilizing a converter to draw power from the first connector 106 and by using one or more auxiliary power sources (e.g., the solar panels 134), the charging system 200 may ensure that auxiliary battery 120 is adequately charged and ready to power the trailer motor 112 when needed.

According to some embodiments, the charging system 200 implements a current measuring algorithm to determine the current to be used on the auxiliary power line and limits the current being drawn by the charging system 200 to a safe current to ensure that the current on the line does not exceed a line current limit (of, e.g., 30 A). The power on the line is limited to 360 watts and the charging system 200 ensures that the power on the circuit is limited to a value below this line power limit (e.g., limited to about 310 watts).

In some embodiments, the charging system 200 performs a test to determine the power draw on the auxiliary line of the trailer 104 in the absence of battery charging. Based on this determination and the line power and current limits, the charging system 200 calculates a maximum power draw for the charging system 200, which ensures that act of charging the auxiliary battery does not cause the line current and power limits to be exceeded. For example, the charging system 200 may limit the power to a nominal value of about 300 W.

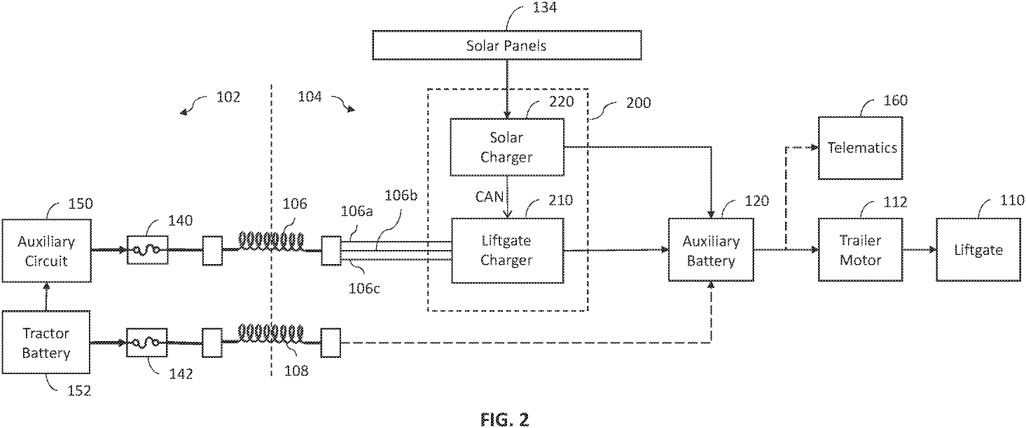

FIG. 2 is a block diagram illustrating a first configuration of the charging system 200, according to some embodiments of the present disclosure.

Referring to FIG. 2, in some embodiments, the charging system 200 includes a battery charger (e.g., a liftgate battery charger) 210 configured to receive electrical power from the auxiliary power line 106a of the trailer 104, to regulate this power (e.g., via a DC-DC converter), and to supply the regulated power to the auxiliary battery 120. The regulated output voltage of the battery charger 210 may be about 14.1 VDC to about 14.7 VDC (e.g., about 14.4 VDC). The auxiliary power line 106a is connected to the auxiliary wire/circuit (e.g., the blue wire) of the first connector 106 (e.g., the SAE J560 connector).

The battery charger 210 generally shares this power line 106a with the ABS/EBS 130 of the trailer 104, and any other accessories on the trailer 104 that draw power. The auxiliary power line 106a is in line with a first fuse 140 (e.g., a 30 A resettable fuse) in the tractor 102. To prevent this fuse 140 from being blown and jeopardizing the safety and operability of the vehicle 100, the battery charger 210 has a current limit function that maintains the power draw on this line to safe levels that do not exceed the rating of the first fuse 140. This function will be discussed further below. The input to the first fuse 140 may be indirectly coupled to the tractor battery 152 via a switchable connection 150, which may be through the dashboard of a tractor 102 and its constituents components (e.g., the ECU system). The auxiliary power line 106a provides a 12 V or 24 V input to the battery charger 210 that is available when the tractor 102 is attached to the trailer 104 and the tractor key is in the “on” position, which allows the tractor 102 to output the power necessary to charge the auxiliary batteries 120 of the trailer 104.

In some embodiments, the charging system 200 also includes a solar charger 220 that is configured to receive electrical power from solar panels 134 that may be mounted on the roof of the trailer 104 and to output a regulated power (with, e.g., a 14.4 DC voltage) that may be used to charge the auxiliary battery 120. The solar charger may include a DC-DC converter (e.g., a buck regulator, a boost regulator, a buck-boost regulator, etc.) that can generate a constant voltage output based on the variable input solar power. In some embodiments, the outputs of the battery charger 210 and the solar charger 220 are separately connected to the auxiliary battery 120 thus allowing the two chargers 210 and 220 to independently and concurrently (e.g., simultaneously) charge the auxiliary battery 120. However, embodiments of the present disclosure are not limited thereto, and in examples in which the trailer 104 does not have any solar panels mounted thereto, the charging system 200 may lack a solar charger 220.

In some examples, the auxiliary battery 120 may also receive electrical power from the second connector (e.g., the dual-pole stinger cord) 108, which may be connected to the tractor battery 152 via a second fuse 142 (e.g., a 30 A fuse). This almost-direct electrical connection to the tractor battery 152 allows the auxiliary battery 120 to be charged even when the tractor key is in the “off” position. However, as the second connector 108 presents a second connection that has to be made by a driver when the tractor hooks up to a trailer, this connection is not always established. Further, this extra connection may present an additional set of issues that would require troubleshooting (such as corrosion of the contacts, broken wires, etc.), which may lead to some fleet owners/drivers opting out of using this connection. As such, in some examples, this additional charging path may not be available to the auxiliary battery 120.

In additional to being a primary source of power to the trailer motor 112 (which drives the liftgate 110), the auxiliary battery 120 may be a primary source or a supplemental source of power for one or more devices including a trailer telematics device 160, power-on circuitry of the liftgate and solar chargers 210 and 220, etc.

According to some embodiments, the battery charger 210 is capable of accurately estimating the state of charge (SOC) and the state of health (SOH) of the auxiliary battery 120 by monitoring the amount of energy supplied to the auxiliary battery 120 over time. While the battery charger 210 is aware of the amount and rate of energy it provides to the auxiliary battery it has no independent knowledge of the charge provided by the solar charger 220. As such, in some embodiments, the solar charger 220 interfaces with the battery charger 210 via a communication protocol such as control area network (CAN). The CAN messages transmitted by the solar charger 220 may provide information relating to the current status of the solar charger 220 (e.g., charging/not charging and output power level) as well as historical charge data (together referred to herein as solar charging data), which allows the battery charger 210 to more accurately calculate the SOC and SOH of the auxiliary battery 120 when juxtaposed with the charge energy calculation internal to the battery charger 210. In some examples, the battery charger 210 estimates SOC and SOH by utilizing a coulomb counting algorithm or a variation thereof. However, embodiments of the preset disclosure are not limited thereto, and any suitable estimation method such as a voltage measurement method or the Kalman filter method may be employed.

In some embodiments, the battery charger 210 utilizes the instantaneous CAN data received from the solar charger 220 to determine whether the battery charger should participate in the charging of the auxiliary battery 120 given the instantaneous SOC of the auxiliary battery 120.

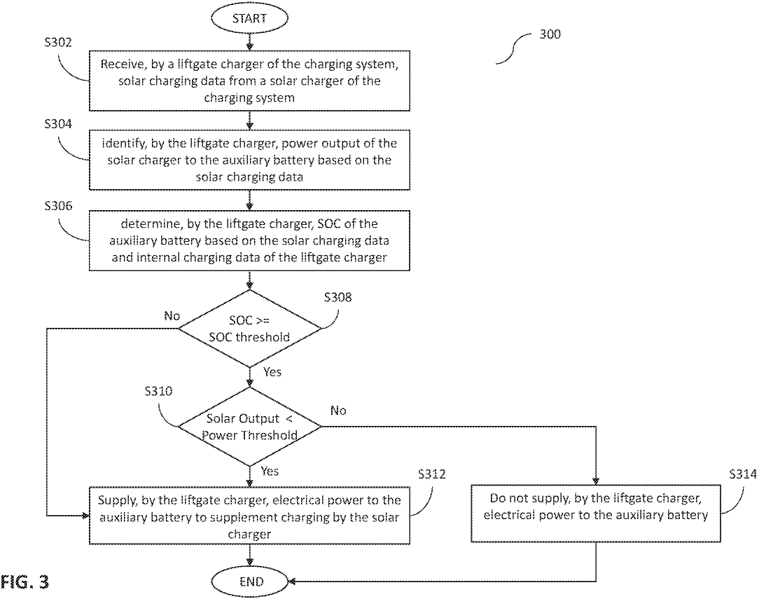

FIG. 3 is a flow diagram illustrating a process of prioritizing solar charging by the battery charger 210, according to some embodiments of the present disclosure.

Referring to FIG. 3, in some embodiments, the battery charger 210 receives solar charging data from the solar charger of the charging system (S302), for example, by way of the CAN bus that communicatively couples at least the liftgate and solar chargers together 210 and 220. The battery charger 210 then identifies the power output of the solar charger 220 to the auxiliary battery 120 based on the solar charging data (S304).

The battery charger 210 then determines state of charge (SOC) of the auxiliary battery 120 based on the solar charging data and internal charging data of the battery charger 210 (S306). Here, the solar charge data may include data indicating status of the solar charger 220 as charging or non-charging, an output power level of the solar charger 220, and historical data indicating amount of energy the solar charger 220 has delivered to the auxiliary battery 120 since last communication with the battery charger 210. Further, the internal charging data may include output power level of the battery charger 210 and cumulative amount of energy provided to the auxiliary battery 120 over time by the battery charger 210.

The battery charger 210 then compares the SOC with an SOC threshold (e.g., 90%; S308).

When the SOC is greater than or equal to the SOC threshold, the battery charger 210 compares the power output of the solar charger 220 with a power threshold (e.g., 12 W; S310). When the solar output is less than the power threshold, the battery charger 210 determines that the solar charger 220 alone is not capable of supplying sufficient charge to the auxiliary battery 120 and thus supplies regulated electrical power that is sourced from the auxiliary power line 106a of the trailer 104 to the auxiliary battery 120 to supplement charging by the solar charger 220 (S312). This ensures that the auxiliary battery 120 has sufficient charge to drive the liftgate 110 as well as other sink devices during normal operation. However, when the solar charger output power is reported to be greater than or equal to the power threshold (e.g., 12 W), the battery charger 210 will not source additional charging power to the auxiliary battery 120 and will allow the solar charger 220 to charge and maintain the auxiliary battery 120 (S314), thus alleviating the use of fossil fuels and reducing operational costs of the vehicle 100.

When the SOC is less than the SOC threshold (e.g., 90%), the battery charger 210210 sources additional charging power to the auxiliary battery 120 either in conjunction with or in the absence of solar charger energy.

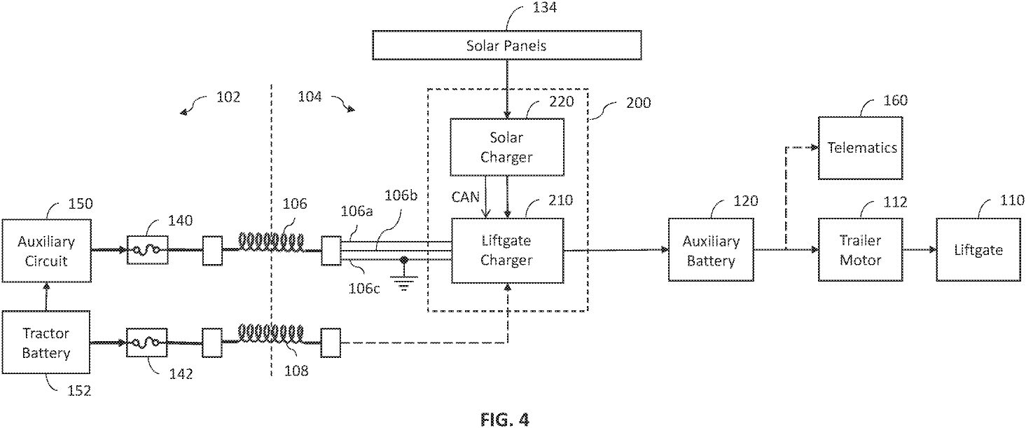

FIG. 4 is a block diagram illustrating a second configuration of the charging system 200, according to some embodiments of the present disclosure.

The second configuration of the charging system 200 that is illustrated in FIG. 4 is substantially the same as the first configuration illustrated in FIG. 2, except that the solar charger 220 and the second connector 108 no longer directly provide power to the auxiliary battery 120 and instead source any electrical power to the auxiliary battery 120 through the battery charger 210. In some embodiments, the solar charger 220, and the second connector 108 when available, provide power to the input of the battery charger 210, which uses the input power that is provided by any source (e.g., the first connector 106, the solar charger 220, and/or the second connector 108) to provide a regulated output to the auxiliary battery 120. In other words, the battery charger 210 acts as the sole source of power to the auxiliary battery 120.

Referring to FIGS. 2 and 4, in addition to receiving a 12/24 VDC input from the auxiliary power wire of the first connector 106 (e.g., SAE J560 pin #7), the battery charger 210 receives a brake light input 106b (e.g., SAE J560 pin #4) from the first connector 106. While the auxiliary power line 106a is the charger’s primary source of power for auxiliary battery charging, the brake light input 106b is intended solely for control of the state (e.g., mode of operation) of the battery charger 210. In some embodiments, when the brake light input is high (e.g., is 12 VDC), indicating the vehicle’s brakes (e.g., ABS/EBS 130) are engaged, the battery charger 210 enters into “safe mode”. The charger 210 then resumes normal charging when the brake is released, and the brake light input 106b goes low (e.g., becomes substantially 0 V).

In safe mode, the battery charger 210 limits the current drawn by the input of the battery charger to a low level value (e.g., limits it to 5 A) to ensure that there is sufficient current available on the auxiliary power line 106a to drive the ABS/EBS 130 and allow for safe braking of the vehicle 100. In some examples, when in safe mode, the battery charger 210 completely disables charging of the auxiliary battery 120 to minimize current draw on the auxiliary power line 106a until the brake light signal returns to a low value (e.g., 0 V).

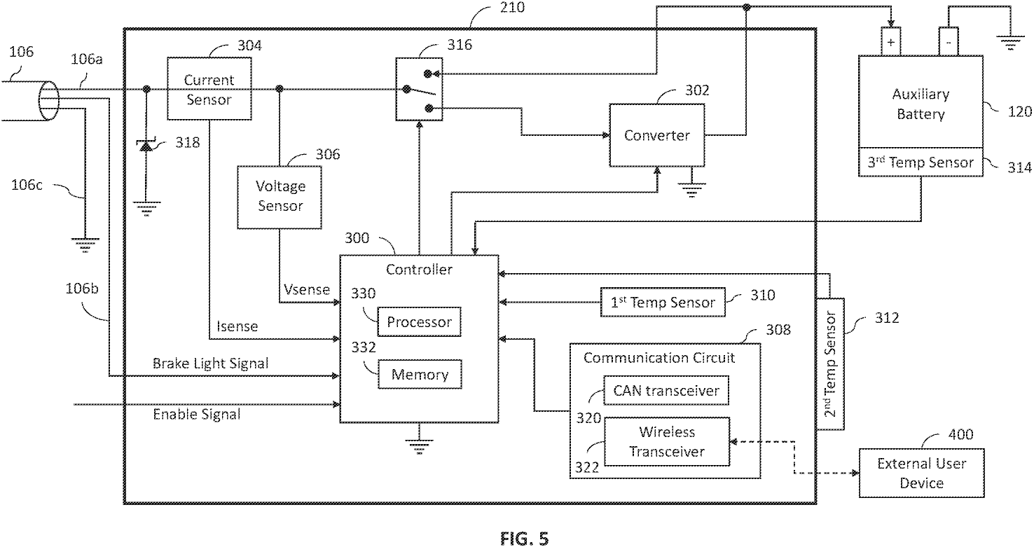

FIG. 5 illustrates a schematic diagram of the battery charger 210 according to some embodiments of the present disclosure.

Referring to FIG. 5, in some embodiments, the battery charger 210 includes a controller 300, a converter (e.g., a DC-DC converter) 302, a current sensor 304, a voltage sensor 306, a communication circuit 308, a first temperature sensor 310, a switch 316, and a protection circuit 318. In some examples, the battery charger 210 may include or interface with a second and third temperature sensors 312 and 314.

In some embodiments, the converter 302 includes a DC-DC converter, such as a boost regulator, a buck regulator, a buck-boost regulator, or the like. The converter 302 may be able to regulate an input ranging from about 9 V to about 46 V to a desired output voltage of, for example, about 14.4 V. The battery charger may provide galvanic isolation and may be 95% or more efficient in the stated operational range.

The current sensor 304 measures the input current (e.g., the instantaneous input current) to the battery charger 210 and reports the sensed current to the controller 300 for processing. The current sensor 304 may be a hall effect current sensor, a resistive sensor that utilizes a shunt resistor and a high speed amplifier, or the like. The voltage sensor 306 measures the line voltage of the auxiliary power line 106a which is input to the battery charger 210 and reports the measurement to the controller 300 for processing. In some embodiments, when the input voltage on the auxiliary power line 106a drops below a percentage threshold (e.g., 60%) of the expected value of 12 VDC or 24 VDC, the controller 300 places the battery charger 210 in safe mode and limits the power intake to a low power level (e.g., 120 W) for the current cycle (and in some examples, the next cycle). A cycle (e.g., a power cycle) may refer to a duration of time between successive power resets of the auxiliary power input (i.e., auxiliary power line voltage dropping to a low value such as 0 V and then increasing back up to the expected 12/24 VDC). For the duration of the time that the battery charger 210 is operating at the low power level, it is considered to be in safe mode. This feature may protect against instances when a device that is supplying the source current to the auxiliary power line 106a has a current limit that is lower than that of what the battery charger 210 is attempting to draw.

For example, this protects the auxiliary circuit 150 and the first fuse 140 when a trailer tester (e.g., an ABS tester) is connected and testing the ABS 130. A trailer tester may only have 15 A maximum current output on the J560 auxiliary power line. Without this safety feature, if the battery charger 210 powers up (e.g., wakes up) while the auxiliary power line 106a is powered by the trailer tester and not the tractor 102, an attempt by the battery charger 210 to ramp up its current draw to a high level (e.g., close to 30 A) may cause the trailer tester to enter a loop where it’s self-resetting fuse keeps blowing, then resetting. This may cause a technician to observe an unexpected/odd battery input voltage (e.g., observe 5 VDC on a digital voltmeter) and incorrectly determine that the battery charger 210 has malfunctioned (e.g., by pulling the input line voltage down and not charging the auxiliary battery 120). By entering safe mode and limiting the power/current draw from the auxiliary power line 106a when the input voltage drops below the percentage threshold (e.g., 60%) of the expected value, the battery charger 210 prevents the trailer tester from entering such a loop, thus avoiding the misdiagnosis by the technician and an unnecessary downtime of the trailer.

In some embodiments, the first temperature sensor 310 allows the controller 300 to monitor the internal temperature of the battery charger 210 and if it senses an unsafe condition (e.g., if the temperature is too high or too low), it stops the charging of the auxiliary battery 120 by the converter 302.

The battery charger 210 may also monitor the ambient temperature surrounding the charger 210. For example, a second temperature sensor 312 for measuring ambient temperature may be integrated into the housing of the charger 210, or the second temperature sensor 312 may be a remote sensor that is integrated into the charger’s bulkhead connector. In some examples, the second temperature sensor 312 may also be CAN-based temperature sensor integrated into the harness of the charger 210. In addition to monitoring the temperature of the battery charger 210, the controller 300 may also have the ability to monitor the temperature of the auxiliary battery 120 by virtue of a CAN-based third temperature sensor 314 that may be attached to auxiliary battery 120. Each of the first to third temperature sensors may be a negative temperature coefficient (NTC) thermistor, a resistance temperature detector (RTD), a thermocouple, a semiconductor-based sensor, or the like.

The communication circuit 308 may include a CAN transceiver 320 coupled to the CAN bus of the trailer 104, which is capable of transmitting and receiving messages via the CAN bus. For example, CAN transceiver 320 is configured to receive the solar charge data reported by the solar charger 220 and to transmit this information to the controller for determining the SOC and/or the SOH of the auxiliary battery 120. The CAN network may be based on SAE J1939 and ISO 11898-2, running at a selective baud rate (e.g., 250K baud). In some examples, the solar charger 220 may communicate faults from the solar charging system to the battery charger 210 through the CAN bus. The battery charger 210 may use this information in determining what source to utilize in charging the battery.

The communication circuit 308 may also include a wireless transceiver 322 configured to wirelessly send data to and receive data an external user device 400 (e.g., a mobile phone or tablet). The wireless transceiver 322 may be configured to communicate over wifi and/or bluetooth. This allows a user to wireless program/set one or more control parameters of the battery charger 210. For example, the user may set voltage input level of the battery charger to 12 V or 24 V via bluetooth or wifi. In some examples, the user may set the baud rate of the CAN network to one of the following values via bluetooth or wifi connection: 250k baud, 500k baud, 500k baud CAN FD format, and 1M baud CAN FD format.

Additionally, the wireless transceiver 322 may also allow the external user device 400 to receive battery prognostic information from the battery charger 210. In some embodiments, the battery charger 210 (e.g., the controller 300) is configured to calculate the approximate state of health (SOH) and/or remaining useful life (RUL) of the auxiliary battery 120 within three stages, beginning of life (BoL), middle of life (MoL), and end of life (EoL), and to report this as part of the prognostic data provided to the external user device 400. BoL may indicate that, based on the calculation of the battery charger 210, the auxiliary battery 120 appear to be in good health and there is less than a 20% chance that the auxiliary battery 120 will fail in the next 3 months. MoL may indicate that, based on the calculation of the battery charger 210, the auxiliary battery 120 has a 40 to 70% chance of failing in the next 3 months. EoL may indicate that, based on the calculation of the battery charger 210, the auxiliary battery 120 has a 70% chance of failing in the next 3 months. The battery charger 210 (e.g., the wireless transceiver 322) may also communicate to the external user device 400 the SOC of the auxiliary battery 120 as well as other information. For example, the battery charger 210 may report if the auxiliary battery 120 is not charging and needs to be replaced. In some examples, the battery charger 210 may utilize the incoming CAN messages from the solar charger 220 to support the advertisement of overall solar charge energy as compared to all other sources for tax reporting purposes. Also, the battery charger 210 may wirelessly communicate any faults reported by the solar charger 220 to the external user device 400 or communicate such faults to the telematics device 160 of the trailer 104 via CAN. Other parameters monitored by the controller 300 and advertised via CAN or a wireless connection include, the instantaneous auxiliary power line voltage, input voltage mode (e.g., 12 V or 24 V), ambient temperature, the charger’s internal temperature, battery temperature, charger load current, input float current, the cumulative amount of energy provided to the auxiliary battery 120 over time by each of the battery charger 210 and the solar charger 220, charger root mean square (RMS) power output, status of safe mode (e.g., as on or off), the lifetime liftgate cycle counter, the trip liftgate cycle counter, and/or the like.

In some examples, the battery charger 210 may have the ability to monitor the liftgate cycles (the operation of the liftgate going up or down) based on voltage drops on the output side of the charger 210 (i.e., the auxiliary battery voltage). The charger 210 may have two variable parameters that may be wirelessly configurable (e.g., via bluetooth): voltage drop, and voltage drop duration. Those values may be set by the user, and each time the condition set by the parameters is met it may be considered as one liftgate cycle. When a liftgate cycle is detected, the battery charger 210 may increment two counters: the lifetime liftgate cycle counter and the trip liftgate cycle counter. The lifetime counter may not be reset and will initially be set at 0, its value will remain persistent in the event of a software update. The trip counter may be reset by the external user device 400.

The protection circuit 318 may protect the input of the battery charger 210 against transients and large voltage spikes. The protection circuit 318 may include a zener diode connected between the auxiliary power line 106a and the ground line 106c at the input of the battery charger 210. However, embodiments of the present disclosure are not limited thereto, and any suitable means of sinking large transient currents at the auxiliary power input may be utilized. The ground line 106c, which may be electrically connected to and be at the same potential as the ground pin of the first connector 106 (e.g., the SAE J560 pin #1), acts as the common ground reference for many if not all of the electrical devices at the trailer 104 including the liftgate and solar chargers 210 and 220, the auxiliary battery 120 and the trailer motor 112.

In some embodiments, the battery charger 210 has an enable feature that can enable/disable the charger 210 based on an enable signal. This enable feature of the battery charger 210 may also be turned off (e.g., via bluetooth) so that the battery charger 210 is always activated/enabled, irrespective of the enable signal, when the appropriate input voltage is present at the auxiliary power line.

The controller 300 may include a processor (or processing circuit) 330 and an internal memory 332 having stored thereon instruction that when executed by the processor 330 cause the processor to perform the actions described herein with reference to the controller 300. The term “processing circuit” or “processor” is used herein to include any combination of hardware, firmware, and software, employed to process data or digital signals. Processing circuit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs). In a processing circuit, as used herein, each function is performed either by hardware configured, i.e., hard-wired, to perform that function, or by more general purpose hardware, such as a CPU, configured to execute instructions stored in a non-transitory storage medium. A processing circuit may be fabricated on a single printed wiring board (PWB) or distributed over several interconnected PWBs. A processing circuit may contain other processing circuits; for example, a processing circuit may include two processing circuits, an FPGA and a CPU, interconnected on a PWB.

According to some embodiments, the battery charger 210 limits its current or power intake based on the level current draw on the auxiliary power line 106a by components other than the charger 210 itself. The battery charger 210 determines this current draw by supplying power to the auxiliary power line 106a while the line 106a is unpowered and measures the current draw from all other ancillary devices on the auxiliary power line 106a in order to determine the maximum current it can safely draw from the auxiliary circuit 150. The charger may use this to set and limit the maximum current input to the charger 210 to maintain a target power on the auxiliary power line of, for example, about 300 W.

In some embodiments, the power reversal performed by the battery charger 210 during a current limit test is enabled by the switch 316, which is coupled between the auxiliary power line 106a, the converter 302, and the auxiliary battery 120. In response to a control signal from the controller 300, the switch 316 can selectively couple the input of the converter 302 or the auxiliary battery 120 to the auxiliary power line 106a. During normal operation, the controller 300 signals the switch 316 to electrically couple the auxiliary power line 106a to the converter 302 to allow the line 106a to source current to the converter 302 for charging the auxiliary battery 120. When performing a power reversal during the current limit test, the controller 300 signals the switch to decouple the input of the converter 302 from the auxiliary power line 106, and to couple the line 106a to the auxiliary battery 120, so that the battery 120 can acts as a source of power to the components coupled to the auxiliary power line 106a.

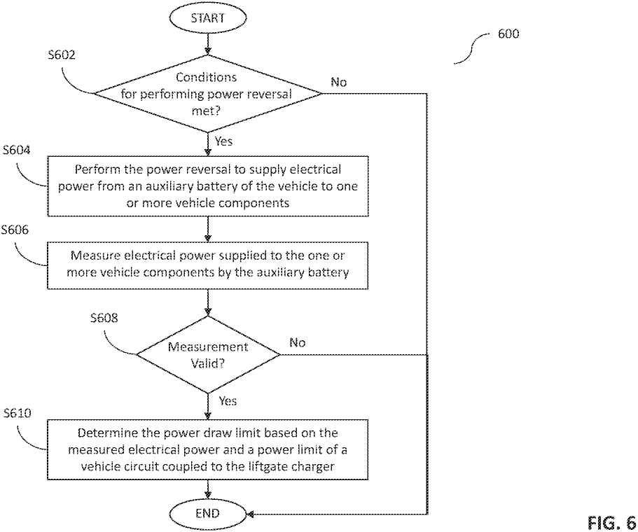

FIG. 6 is a flow diagram illustrating a process 600 of determining a power draw limit of the battery charger 210 according to some embodiments of the present disclosure.

In some embodiments, before performing the current limit test, the battery charger 210 determines whether the conditions are met for performing a power reversal (S602).

When the conditions are met, the battery charger 210 performs the power reversal to supply electrical power from the auxiliary battery 120 of the vehicle 100 to one or more vehicle components, such as a solar charger 220 and/or a telematics device 160 (S604). When the conditions are not met, the battery charger 210 does not perform the current limit test and waits to do so until the conditions are satisfied.

In some embodiments, the battery charger 210 performs power reversal by coupling (via the switch 316) the auxiliary battery 120 to the auxiliary power line 106a of the trailer 104 that is coupled to the one or more vehicle components, and decoupling (via the switch 316) the input of the converter 302 from auxiliary power line 106a.

After performing the power reversal, the battery charger 210 then measures the electrical power supplied to the one or more vehicle components by the auxiliary battery (S606). Next, the battery charger 210 determines whether the measurement is valid (S608). Here, the battery charger 210 stops providing power to the auxiliary power line 106a and measures the input voltage on the line 106a to determine if power was restored from another source during the course of the test. If voltage is measured on this input following the test, the test is invalid. If no voltage is measured on this input following test completion, the test is valid.

In response to the determining the validity of the measurement, the battery charger 210 determines the power draw limit based on the measured electrical power and a power limit of a vehicle circuit coupled to the battery charger (S610). For examples, the battery charger 210 may calculate the power draw limit as a difference between the power limit of the vehicle circuit and the measured electrical power. The calculated power draw limit is the amount of power that the battery charger 210 can now safely draw from the auxiliary power line 106a without exceeding the power capability of the auxiliary circuit 150, considering the other loads visible to it on the circuit.

Here, when the results are not valid, the battery charger 210 does not calculate or recalculate the value of the power draw limit. If not charger 210 has not succeeded in running any power limit tests in the past, it will enter safe mode and limit its power input (to, e.g., 120 W) until the next power cycle.

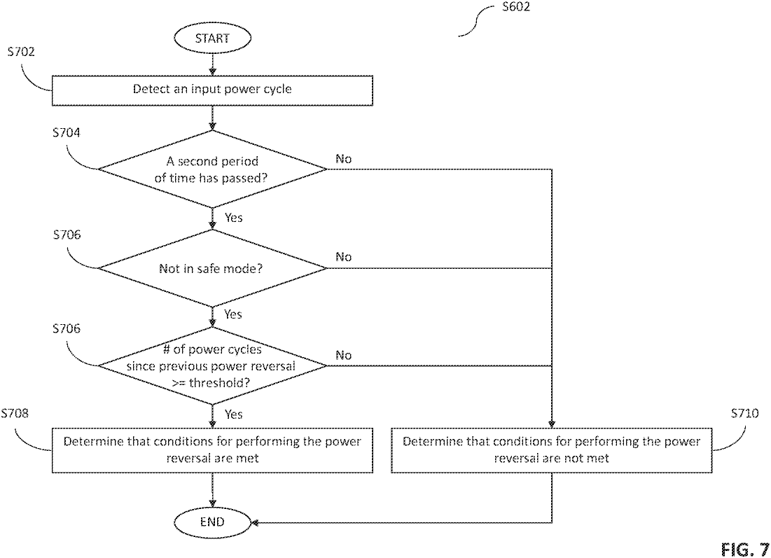

FIG. 7 is a flow diagram illustrating a process S602 of determining whether the conditions for performing the power reversal are met, according to some embodiments of the present disclosure.

According to some embodiments, the battery charger 210 determines that the power reversal conditions are satisfied, by first detecting an input power cycle (S702). It may do so by detecting a voltage collapse (or a sudden voltage drop) at the input of the battery charger 210 and determining that the voltage collapse has lasted for a first period of time (e.g., about 5 minutes). By checking whether the auxiliary power line has been at about zero volts for the first period of time, the battery charger 210 ensures that it is not responding to a power transient or voltage spike, but rather to an actual power cycle. The depth of the voltage collapse and the first period of time may be programmable parameters set by a user.

The battery charger 210 then determines whether a number of conditions are met (S704-S706). For example, the charger 210 waits until a second period of time (e.g., 20 seconds) has passed since the input power cycle before proceeding (S704), it checks to ensure that the charger 210 is in not in safe mode (S706) as this mode may indicate a non-normal condition on the auxiliary power line 106s, and that a number of input power cycles since a previous power reversal is greater than or equal to a threshold (e.g., 10 power cycles), which ensures that the current limit test is not performed too frequently. When the conditions are satisfied, the battery charger 210 determines that it may proceed with the power reversal (S708), and if any of these conditions are not satisfied, power reversal is not performed (S710). The battery charger 210 may enter safe mode when it detects a brake signal at a brake light input 106b of the trailer 104 or when it detects a drop in an input voltage of the battery charger during a current ramp up.

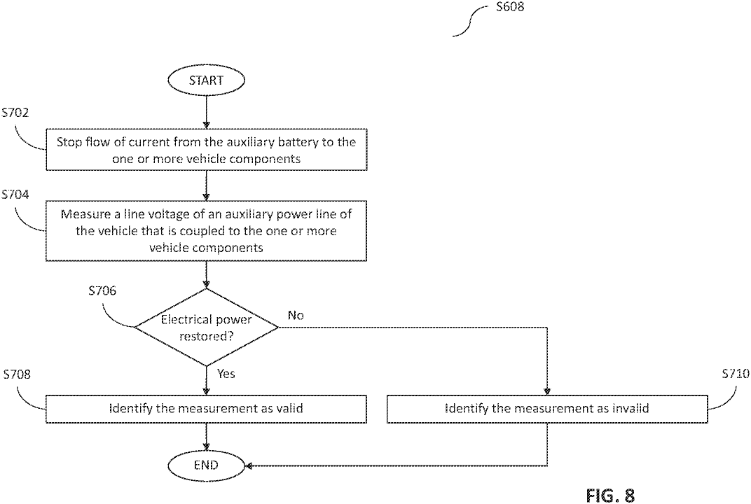

FIG. 8 is a flow diagram illustrating a process S608 of determining whether the measurement performed is valid, according to some embodiments of the present disclosure.

In some embodiments, the battery charger 210 stops the flow of current from the auxiliary battery 120 to the one or more vehicle components (S702), measures the line voltage of the auxiliary power line 106a that is coupled to the one or more vehicle components (S704). When the battery charger 210 determines that electrical power has not been restored at the auxiliary power line 106 based on the line voltage (S706), the charger 210 identifies the measurement as valid (e.g., by measuring the line voltage as zero volts; S708). Otherwise, the measurement is deemed to be invalid, which leads to the charger 210 not calculating/recalculating the value of the power draw limit (S710).

Accordingly, as described above, the battery charger reduces downtime due to blown fuses on the auxiliary power line, reduces maintenance man hours due to increasing the tools available to fleets to diagnose discrepancies quicker, reduces man hours related to troubleshooting failed ABS tests, and increases efficiency in the charging of the liftgate batteries.

While in some examples, the auxiliary battery 120 may be a liftgate battery, embodiments of the invention are not limited thereto. For example, the auxiliary battery 120 may be a battery bank used to power a forklift, a pallet jack, and/or the like. Further, the battery charger 210 may be used, in some embodiments, to manage power to devices other than an auxiliary battery, for example, auxiliary lights, sensors, and/or the like.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and equivalents thereof.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

The terminology used herein is for the purpose of describing particular embodiments and is not intended to be limiting of the inventive concept. It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

The terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

The battery charger and/or any other relevant devices or components according to embodiments of the invention described herein may be implemented utilizing any suitable hardware, firmware (e.g., an application-specific integrated circuit), software, or a suitable combination of software, firmware, and hardware. For example, the various components of the controller may be formed on one integrated circuit (IC) chip or on separate IC chips. Further, the various components of the controller may be implemented on a flexible printed circuit film, a tape carrier package (TCP), a printed circuit board (PCB), or formed on a same substrate as the controller. Further, the various components of the controller may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the invention.

What is claimed is:

1. A method of determining a power draw limit of a battery charger of a vehicle, the method comprising:
performing a power reversal to supply electrical power from an auxiliary battery of the vehicle to one or more vehicle components;
measuring electrical power supplied to the one or more vehicle components by the auxiliary battery;
determining validity of the measurement; and
in response to the determining the validity of the measurement,
determining the power draw limit based on the measured electrical power and a power limit of a vehicle circuit coupled to the battery charger.

2. The method of claim 1, wherein the performing the power reversal comprises:
coupling the auxiliary battery to an auxiliary power line of the vehicle that is coupled to the one or more vehicle components; and
decoupling an input of the battery charger from the auxiliary power line.

3. The method of claim 1, further comprising:
determining that conditions for performing the power reversal are met,
wherein performing the power reversal is in response to the determining that the conditions for performing the power reversal are met.

4. The method of claim 3, wherein the determining that conditions for performing the power reversal are met comprises:
detecting an input power cycle; and
determining that at least one of a first condition, a second condition, and a third condition are met,
the first condition being a second period of time having passed since the input power cycle,
the second condition being the battery charger not being in a safe mode, and
the third condition being a number of input power cycles since a previous power reversal is greater than or equal to a threshold.

5. The method of claim 4, wherein the battery charger is configured to enter the safe mode in response to determining one or more of:
detecting a brake signal at a brake light input of the vehicle, and
detecting a drop in an input voltage of the battery charger below a percentage threshold of an expected input voltage.

6. The method of claim 4, wherein the detecting the input power cycle comprises:
detecting a voltage collapse at an input of the battery charger; and
determining that the voltage collapse has lasted for a first period of time.

7. The method of claim 1, wherein the determining the validity of the measurement comprises:
stopping flow of current from the auxiliary battery to the one or more vehicle components;
measuring a line voltage of an auxiliary power line of the vehicle that is coupled to the one or more vehicle components;
determining that electrical power has not been restored at the auxiliary power line based on the line voltage; and
identifying the measurement as valid.

8. The method of claim 7, wherein that the electrical power has not been restored at the auxiliary power line by measuring the line voltage as zero volts.

9. The method of claim 1, wherein the determining the power draw limit comprises:
calculating the power draw limit as a difference between the power limit of the vehicle circuit and the measured electrical power.

10. The method of claim 1, wherein the vehicle is a tractor-trailer, and
wherein the one or more vehicle components comprise at least one of a solar charger, and a telematics device.

11. A method of charging an auxiliary battery of a vehicle by a charging system, the method comprising:
receiving, by a battery charger of the charging system, solar charging data from a solar charger of the charging system;
identifying, by the battery charger, power output of the solar charger to the auxiliary battery based on the solar charging data;
determining, by the battery charger, a state of charge (SOC) of the auxiliary battery based on the solar charging data and internal charging data of the battery charger; and
in response to determining that the state of charge of the auxiliary battery is greater than or equal to an SOC threshold and the power output of the solar charger is less than a power threshold,
supplying, by the battery charger, electrical power to the auxiliary battery to supplement charging by the solar charger.

12. The method of claim 11, further comprising:
in response to determining that the state of charge of the auxiliary battery is less than the SOC threshold,
supplying, by the battery charger, electrical power to the auxiliary battery to supplement charging by the solar charger.

13. The method of claim 11, further comprising:
in response to determining that the state of charge of the auxiliary battery is less than the SOC threshold or that the power output of the solar charger is greater than or equal to the power threshold,
not supplying, by the battery charger, electrical power to the auxiliary battery.

14. The method of claim 11, wherein the solar charger is configured to receive electrical power from one or more solar panels and to supply regulated power to the auxiliary battery.

15. The method of claim 11, wherein the battery charger is configured to receive electrical power from an auxiliary power line of the vehicle and to supply regulated power to the auxiliary battery.

16. The method of claim 11, wherein the SOC threshold is 90%, and wherein the power threshold is 12 W.

17. The method of claim 11, wherein the solar charge data comprises data indicating status of the solar charger as charging or non-charging, an output power level of the solar charger, and historical data indicating amount of energy delivered to the auxiliary battery since last communication with the battery charger, and
wherein the internal charging data comprises output power level of the battery charger and cumulative amount of energy provided to the auxiliary battery over time by the battery charger.

18. A charger system comprising:
a battery charger configured to receive electrical power from an auxiliary power line of a vehicle and to charge an auxiliary battery of the vehicle;
a solar charger configured to receive electrical power from one or more solar panels of the vehicle and to supply electrical power to the auxiliary battery independent from the battery charger, the solar charger being further configured to provide solar charging data to the battery charger,
wherein the battery charger is configured to determine at least one of a state of charge (SOC) and a state of health (SOH) of the auxiliary battery based on the solar charging data and internal charging data of the battery charger, and to transmit prognostic data corresponding to the auxiliary battery to an external user device, the prognostic data comprising the at least one of the SOC and SOH of the auxiliary battery.

19. The charger system of claim 18, wherein the solar charge data comprises data indicating status of the solar charger as charging or non-charging, an output power level of the solar charger, and historical data indicating amount of energy delivered to the auxiliary battery since last communication with the battery charger, and
wherein the internal charging data comprises output power level of the battery charger and cumulative amount of energy provided to the auxiliary battery over time by the battery charger.

20. The charger system of claim 18, wherein the battery charger is configured to monitor and transmit to the external user device at least one of:
faulty status of the auxiliary battery indicating inability to charge,
fault reports received from the solar charger,
a voltage of the auxiliary power line,
ambient temperature of the battery charger,
internal temperature of the battery charger,
temperature of the auxiliary battery,
output power of the battery charger,
cumulative amount of energy provided to the auxiliary battery over time by each of the liftgate and solar chargers,
a lifetime liftgate cycle counter, and
a trip liftgate cycle counter.
